(19) United States
(12) Patent Application Publication
(10) Pub. No.: US 2024/0260246 A1
(43) Pub. Date: Aug. 1, 2024

(54) Robotic Disassembly System

(71) Applicant: Bright Machines, Inc., San Francisco, CA (US)

(72) Inventors: Shay Arzi, Ram-On (IL); Shaked Bar Ilan, Even-Yehuda (IL); Alex Kuper, Rosh HaAyin (IL); Shlomi Doitsher, Netanya (IL); Avner Salach, Tel-Aviv (IL); Yoni Otman, Ramat Gan (IL); Yonatan Tasama, Netanya (IL); Yehonatan Zait, Netanya (IL)

(21) Appl. No.: 18/424,778

(22) Filed: Jan. 27, 2024

Related U.S. Application Data
(60) Provisional application No. 63/481,985, filed on Jan. 27, 2023.

(51) Int. Cl. H05K 13/00

(52) U.S. Cl. CPC H05K 13/00

(57) ABSTRACT

A method to configure a microfactory line for disassembly of a device is described. The method comprises identifying a configuration of the device for disassembly, determining each action, based on elements on the device to be removed, determining an order of operations based on the configuration of the device. The method further comprises laying out a microfactory including a plurality of robotic cells connected by conveyors, and an end location for each element removed from the device during the disassembly.

### RELATED APPLICATION

The present application claims priority to U.S. Provisional Patent Application No. 63/481,985 filed on Jan. 27, 2023, and incorporates that application by reference in its entirety.

### FIELD

The present invention relates to robotic systems, and more particularly to a robotic disassembly system.

### BACKGROUND

Electronic waste is ubiquitous, with thousands of tons of electronics being thrown away. Data centers especially utilize a large number of devices that are regularly cycled to ensure functionality. Environmentally responsible dispositioning of such electronic devices is a worthwhile goal. Generally, disassembly of such devices is done by hand, which is labor intensive, and may expose the workers to chemicals.

### BRIEF DESCRIPTION OF THE FIGURES

The present invention is illustrated by way of example, and not by way of limitation, in the figures of the accompanying drawings and in which like reference numerals refer to similar elements and in which:

FIG. 1A is an illustration of one embodiment of a disassembly microfactory line.

FIG. 1B is an illustration of one embodiment of a pallet that may be used to hold two servers.

FIGS. 1C-1E are block diagrams of various exemplary configurations of a disassembly line.

FIG. 2A is an overview flowchart of one embodiment of setting up a disassembly microfactory including a plurality of robotic cells.

FIG. 2B is an overview flowchart of one embodiment of designing a microfactory line for disassembly of a set of compatible target devices.

FIG. 3 is an overview flowchart of one embodiment of using the disassembly microfactory.

FIG. 4 is a flowchart of one embodiment of removing the heatsink.

FIG. 5A-5E are diagrams of embodiments of the hardware configuration of the robotic cell for the heatsink removal.

FIGS. 6A-6E are diagrams of embodiments of the end of arm elements for the heatsink removal.

FIG. 7 is a flowchart of one embodiment of removing the central processing unit (CPU).

FIG. 8A is a diagram of one embodiment of the hardware configuration of the robotic cell for the CPU removal.

FIG. 8B is a diagram of one embodiment of a CPU separation unit.

FIG. 8C is an illustration of one embodiment of the hardware configuration of the robotic cell, showing latching.

FIG. 9 is a diagram illustrating one embodiment of a three-stage CPU removal and separation process.

FIG. 10 is an illustration of one embodiment of the tray into which the CPU is placed after removal.

FIG. 11 is a diagram of one embodiment of the end of arm configuration for the CPU removal.

FIG. 12 is a flowchart of one embodiment of the memory module (DIMM) removal.

FIG. 13 is a diagram of one embodiment of the hardware configuration of the robotic cell for the DIMM removal.

FIGS. 14A and 14B are illustrations of embodiments of the configuration for the DIMM sorting.

FIG. 15 is a diagram of one embodiment of the end of arm configuration for the DIMM removal.

FIG. 16 is a block diagram of one embodiment of a computer system that may be used with the present application.

### DETAILED DESCRIPTION

A robotic disassembly method is described. The robotic disassembly method defines a device, or set of devices, to be disassembled, and creates a robotic microfactory to automate the disassembly of the device. The robotic microfactory includes a plurality of robotic cells, each taking one or more actions to disassemble the device. In one embodiment, the instructions on which elements to remove are received from a customer or other entity. For example, for disassembly of a server device, the microfactory may have stations for removing the heatsink(s), removing the central processing unit(s) (CPU), and removing the dual in-line memory modules (DIMMs). In a different disassembly configuration of a server device, the microfactory may have stations for removing the DIMM(s), CPU(s), GPU(s), and flash memory module(s). Other elements may be removed. In one embodiment, the process is designed for reusing components removed from the device and recycling the remaining components and device when possible. Recycling is an important part in reducing the footprint of electronics such as high end servers, which often are decommissioned after only a few years of use. Additionally, the ability to reuse components from a decommissioned device reduces the net cost of the device. In one embodiment, a user indicates which components of the devices should be removed.

The system, in one embodiment, determines how to remove each of the components, and the order of removal, and defines a microfactory line, including one or more robotic cells to perform the removals. Each robotic cell takes one or more actions to disassemble the device. In one embodiment, one or more conveyor belts connect the robotic cells in the microfactory line. Additionally, collection stations may be present at one or more of the robotic cells, to receive the removed elements. In one embodiment, the collection stations may include trays onto which removed components may be placed and/or bins into which removed components may be discarded.

The following detailed description of embodiments of the invention makes reference to the accompanying drawings in which like references indicate similar elements, showing by way of illustration specific embodiments of practicing the invention. Description of these embodiments is in sufficient detail to enable those skilled in the art to practice the invention. One skilled in the art understands that other embodiments may be utilized and that logical, mechanical, electrical, functional, and other changes may be made without departing from the scope of the present invention. The following detailed description is, therefore, not to be taken in a limiting sense, and the scope of the present invention is defined only by the appended claims.

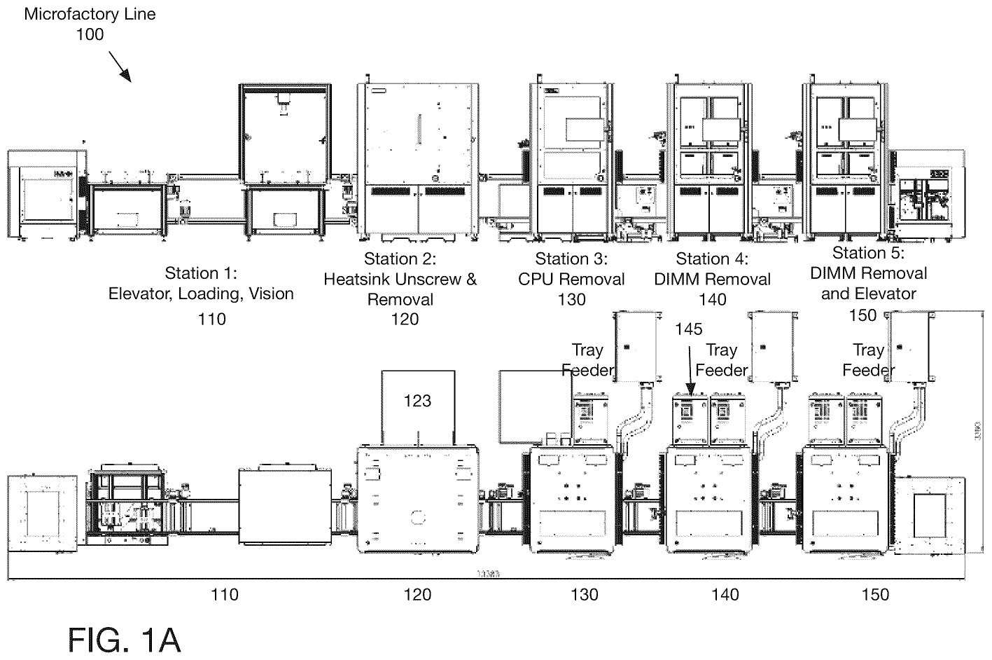

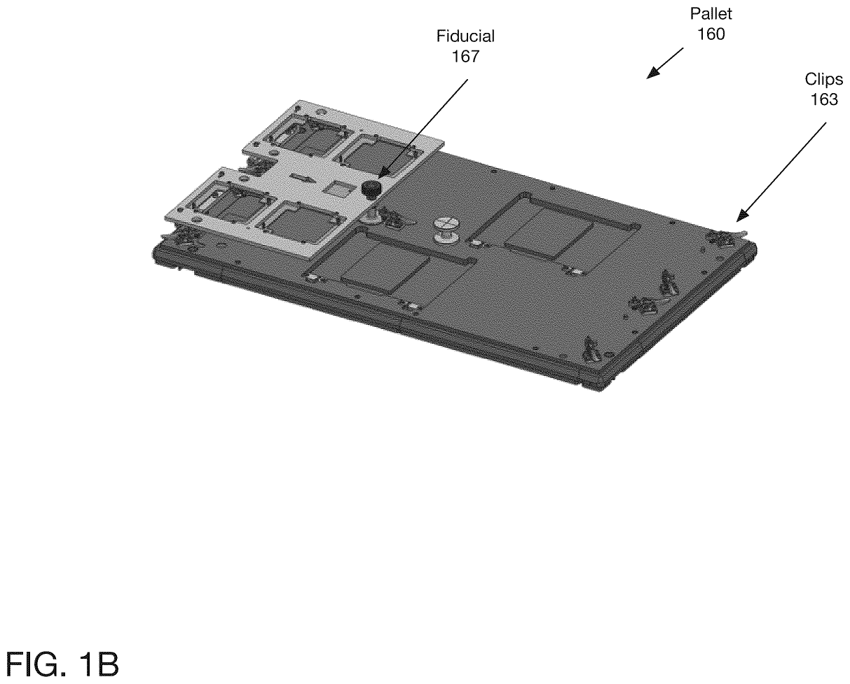

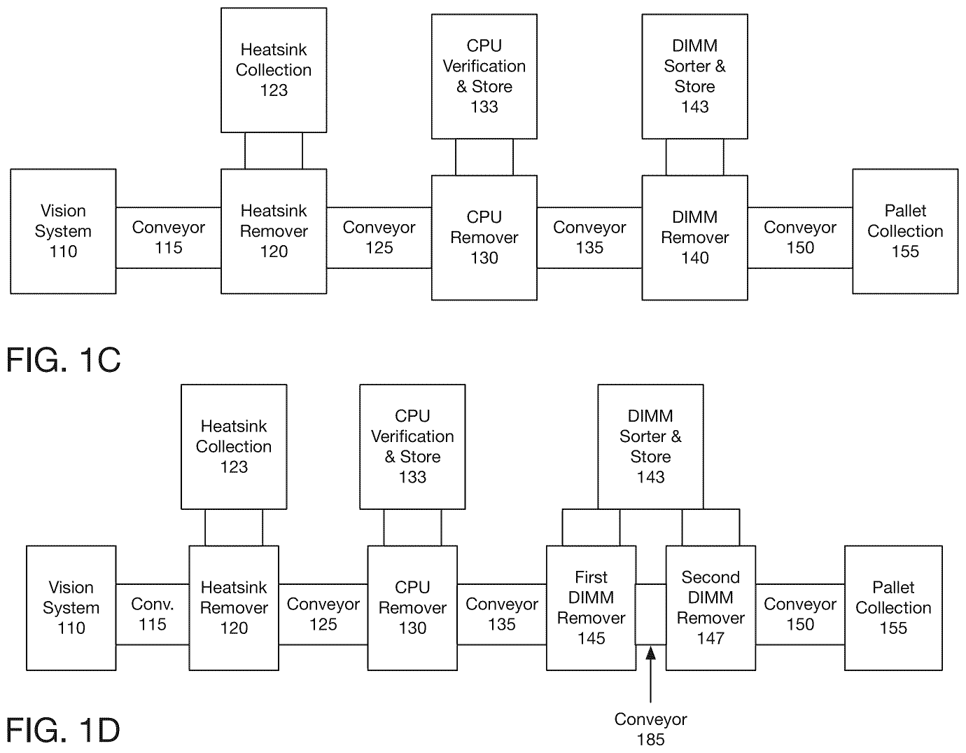

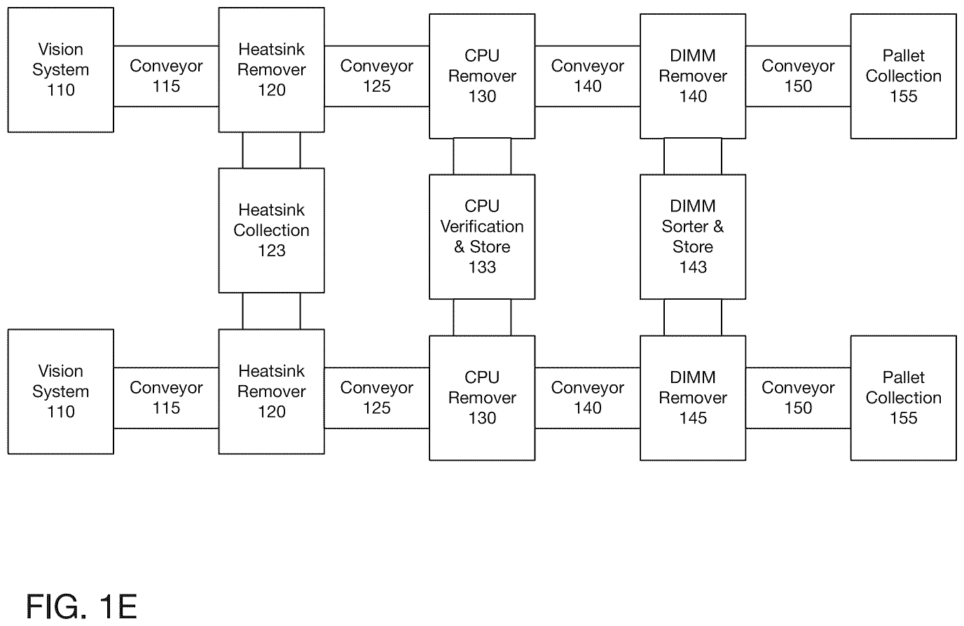

FIG. 1A is an illustration of one embodiment of a disassembly microfactory line, showing a side view, and below that a top view of the microfactory line. This exemplary disassembly microfactory line 100 is to disassemble servers, by removing heatsinks, CPUs, and DIMMs. The first station 110 includes a loading station, on which the servers are placed on pallets for processing. In one embodiment, this is done manually. There is a vision station, which verifies that the pallet is properly positioned and loaded, before sending the pallet to station 2.

The second station 120 is the heatsink removal station. In this station the heatsink(s) are unscrewed from the server device, and removed. As can be seen in the top view illustration, there is a collection station 123, which is the location where the removed heatsinks are collected before the server device is passed to the next station via the conveyor.

The third station 130 is the CPU removal station. The CPU removal station is designed to remove the CPU from the server and place it into a container that is its collection station. In one embodiment, the CPU removal station 130 is customized for the type of CPU attachment mechanism used by the server, as will be described below.

The fourth station 140 is the DIMM (dual in-line memory module) removal. Most servers include a plurality of DIMMs. In one embodiment, each DIMM is removed, scanned, and sorted. In one embodiment, scanning and sorting substation 145 is used. In one embodiment, the sorting separates DIMMs by type/size. In the exemplary setup shown, there are two DIMM removal stations, station 4 140 and station 5 150. The system is designed so that tasks may be split over multiple stations, to optimize the Takt time (the average time interval between the start of disassembly of one unit and the start of disassembly of the next unit when items are produced sequentially). For example, if each of tasks 1, 2, and 3, executed by stations 1, 2, and 3 take 60 seconds to process a pallet including one or more servers, but task 4 executed by station 4 would require 120 seconds, it would slow down the entire process flow. By splitting the task over two robotic cells, station 4 and station 5, the other stations are not idle, while the last task is completed. Note that although this element is referred to as a DIMM, it is a memory board, and may include single inline memory module (SIMM), MicroDIMM, Rambus RDRAM RIMM®, SODIMM, or other memory boards.

After the DIMM removal, the now processed server is placed in a rack, in one embodiment. The resulting output is a container with heatsinks, a container with CPUs, a container with DIMMs, and a container with the now-stripped server. The parts may be reused, recycled, or further processed.

FIG. 1B is an illustration of one embodiment of a pallet 160 that may be used to hold two servers. The pallet 160 in one embodiment includes holding clips 163 to fasten the servers to the pallet. In one embodiment, the pallet 160 is manually loaded. In another embodiment, the loading of the pallet may be automated. The pallet in one embodiment has a fiducial 167 in the middle and provides common support for a variety of types of devices. The exemplary pallet shown is designed to support a variety of types of server devices.

FIGS. 1C-E are block diagrams of various exemplary configurations of a disassembly line described above. FIG. 1C illustrates a default configuration in which a single robotic cell is associated with each task, vision system 110, heatsink remover 120, CPU remover 130, DIMM remover 140, and pallet collection 155 at the end. Each of the set of items removed has an associated collection station, heatsink collection 123, CPU verification and store 133, and DIMM sorter and store 143. The individual robotic cells are connected by conveyors 115, 125, 135, 150.

In contrast, FIG. 1D illustrates the configuration shown in FIG. 1A, with the DIMM removal split over two robotic cells, 145 and 147.

FIG. 1E illustrates a parallel configuration in which two lines are run in parallel, with shared storage of the removed devices. Other configurations may also be used. For example, a single cell may perform two actions, rather than each cell performing a separate action.

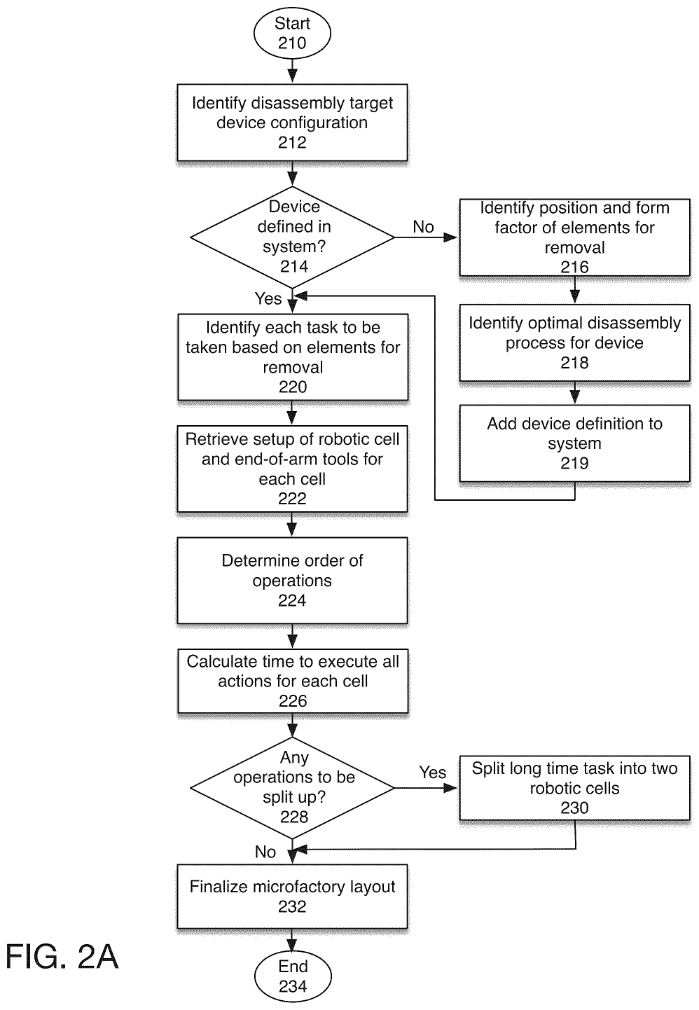

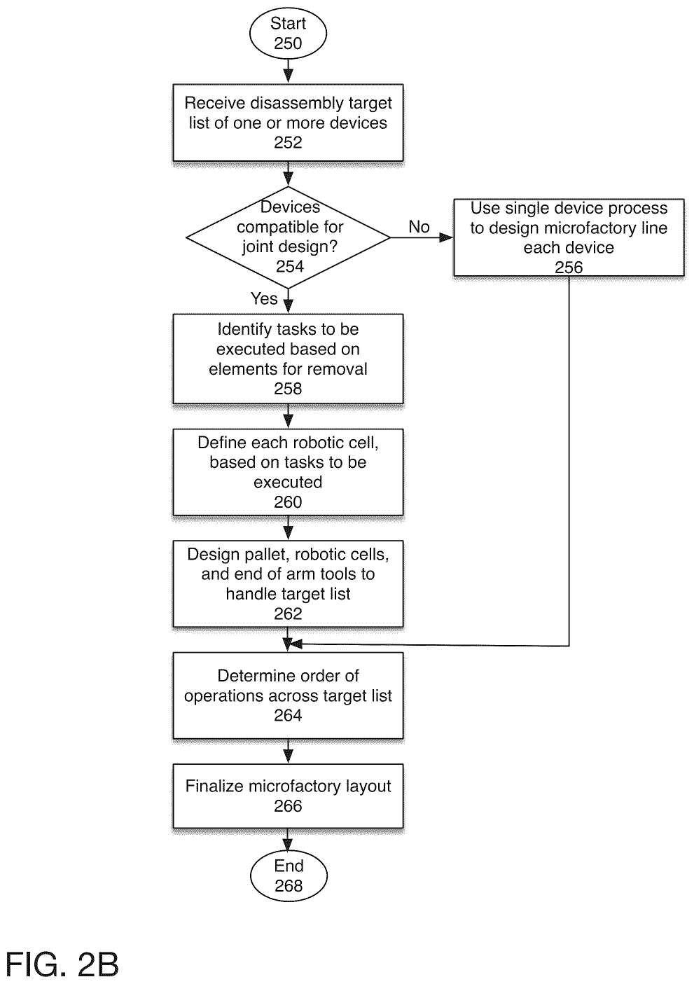

FIG. 2A is an overview flowchart of one embodiment of setting up a disassembly microfactory including a plurality of robotic cells. The process starts at block 210. In one embodiment, this process is initiated when a new device type for disassembly is provided to the system. In one embodiment, portions of this process are executed by engineers or staff members, while others are automated.

At block 212, a disassembly target device configuration is identified. In one embodiment, the disassembly target data may be provided by a customer. The disassembly target may be a particular brand or configuration of server, or other device which includes removable components.

At block 214, the process determines whether the device is defined in the system. The device is defined in the system if it has a configuration that matches a device that has been previously processed. This means that the system is aware of the elements on the device, their positions, and their attachment mechanisms. For example, on a standard server device, the CPU may be attached using a clip and frame, attached as part of a heatsink structure, attached in a frame, or attached using another mechanism. Similarly, there are numerous ways of attaching heatsinks including clips, screws, pins, etc. If the device is defined in the system, the process continues directly to block 220. If the device is not defined in the system, the process continues to block 216.

At block 216, the positions and form factors of the elements for removal are identified. In one embodiment, this information may be provided by providing a sample device. In one embodiment, the configuration may be identified using automated visual systems to inspect the configuration of the device. In one embodiment, the configuration may be identified from a CAD drawing, in which the elements are labeled. The elements to be removed from the device are identified, in one embodiment, based on user input. In one embodiment, an automatic configuration detection may identify elements that could be removed, and the set of elements for removal are selected from the flagged elements. In another embodiment, an image of the board and/or a list of elements for removal may be provided, and the visual identification determines the positions of the elements on the device.

At block 218, the optimal disassembly order for the device is determined. In many cases, the various elements interfere with each other. For example, if the CPU is positioned in close proximity to the heatsink, it is better to remove the heatsink first, before removing the CPU. By appropriately ordering the operations, the process provides more flexibility and less likelihood of interference with the robotic arm or vision system and less likelihood of damaging valuable parts to be removed/reused. The device definition is then added to the system, at block 219. The process then continues to block 220.

At block 220, the actions required for each element's removal are identified. For example, to remove a heatsink that is screwed into a board, the actions may include unscrewing the screws at identified locations, taking the heatsink off the board, and placing the heatsink into a collection container. Thus, a single removal may take multiple actions. Furthermore, each action (e.g., unscrewing the screws) may have further detail actions. For example, for unscrewing one screw, the actions may include: locating the screw, determining the orientation of the screw head, moving the screwdriver over the screw, inserting the screwdriver into the screw head, and turning the screw driver in the unscrewing direction until the screw can be removed because it has been fully unscrewed. Thus, identifying each action identifies the sub-elements required to execute the full action.

At block 222, the system retrieves the setup of the robotic cell and end of arm (EoA) tool(s) for each cell. In one embodiment, a single robotic cell may be used to take multiple actions, which may require different EoA tools. In one embodiment, not all robotic cells in a potential microfactory lineup have the same capabilities. For example, some robotic cells may have two robotic arms, while others have a single arm. Some robotic cells may have additional cameras or other sensors.

At block 224, the system determines the order of operations. As noted above, the optimal disassembly process is defined by the configuration of the device to be disassembled. In one embodiment, the ordering of operations is designed to minimize the risk of damage to valuable components, such as CPUs and GPUs.

At block 226, the time to execute all actions for each cell is calculated. In one embodiment, this includes the time from when a conveyor brings a new pallet with one or more devices into the cell, until the conveyor moves the pallet to the next cell or the end of the line. In one embodiment, this includes any necessary changes in EoA tools, disposal of elements removed from the device, etc.

At block 228, the process determines whether any tasks should be split up. When a particular cell's execution time is significantly longer than the other cells in the microfactory line, the cell's operations may be split across two (or more) robotic cells. This reduces the takt time for the microfactory line. Though each individual device still takes the same amount of time because the next device in line is not held up by the slow board, the overall execution time for the line is reduced.

The split may be done by splitting the set of actions across two robotic cells, a first set of actions taken at a first cell, and a second set of actions done at a second cell, or by duplicating the robotic cells so two robotic cells take half of the devices. If one or more tasks should be split, at block 230, the tasks are split across robotic cells. In some embodiments, if there is a cell that has a very short task, the system may determine whether it would be possible to have that cell execute two tasks. This may be possible, for example, if the system can utilize the same EoA tool for both tasks.

At block 232, the microfactory layout is finalized. In one embodiment, if there is a constraint on the number of robotic cells available for the microfactory that may also be taken into account in finalizing the microfactory layout. For example, as illustrated in FIG. 1E, in one embodiment, the system may be set up with parallel lines, when there are enough robotic cells, to speed up the throughput. The process then ends at block 234.

FIG. 2B is an overview flowchart of one embodiment of designing a microfactory line for disassembly of a set of compatible target devices. The process starts at block 250.

At block 252, the disassembly target list of one or more devices is received. In one embodiment, the target list is defined with the identity, location, and attachment configuration of each of the elements to be removed from each device.

At block 254, the process determines whether the devices are compatible for a joint disassembly design. In one embodiment, when the devices are similar, the microfactory line—including the robotic cells and gantry, end of arm, camera positioning, and pallet—can be designed to be able to handle multiple different devices, which have different configurations. For example, multiple servers may be disassembled by a single microfactory line, without requiring reconfiguration of the individual robotic cells.

If the devices are not compatible, at block 256, the single device process described with respect to FIG. 2A may be used. The process then goes directly to block 264 to finalize the microfactory layout, and end at block 266. In one embodiment, if the system determines what some devices are compatible, and others are not, at the incompatible devices are removed from the list and processed as in block 256, and the remaining target list moves to block 258.

If the devices are compatible, at block 258, each task to be executed on each element for removal is defined. In one embodiment, the actions are aligned across all of the target list of devices.

At block 260, the actions are assigned to robotic cells in the microfactory. This defines the base number of robotic cells, and which actions the robotic cell will take.

At block 262, the system designs the layout of the robotic cells, the end of arm tools, the camera and sensor positions, and the pallet to handle the target list of devices. The pallet carries the device(s) into the robotic cell. The layout of the robotic cell provides the tools and structures to enable removal of the components from the device. This may include additional support structures, such as a CPU separation unit, a chute for collecting removed elements, etc. The end of arm tool is designed to be able to take all actions needed for the target devices.

At block 264, the order of operations is defined across the target list.

At block 266, the microfactory layout is finalized. The process then ends at block 268. In one embodiment, a microfactory line designed with a set of target devices can accept all devices from the target list, without any reconfiguration. In another embodiment, changing between target devices only requires a software change, rather than requiring reconfiguration of the robotic cells. In one embodiment, such a software change can be done automatically, without requiring user intervention.

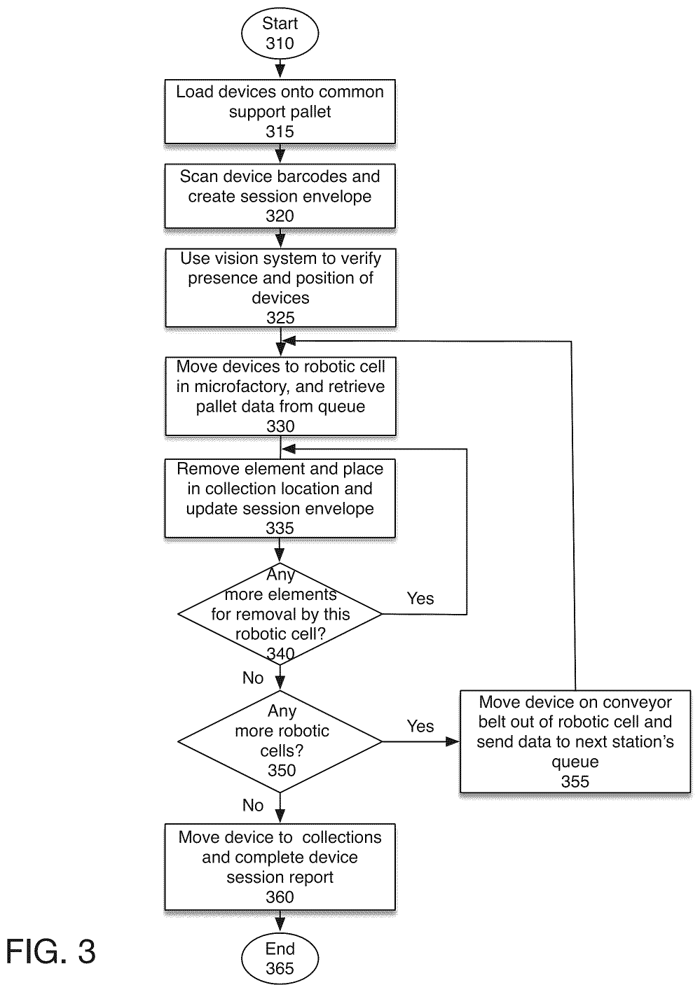

FIG. 3 is an overview flowchart of one embodiment of using the disassembly microfactory. The process starts at block 310.

At block 315, one or more device(s) for disassembly are loaded onto a common support pallet. In one embodiment, this includes affixing one or more devices securely to a pallet. One embodiment of the pallet configuration for a server disassembly system is shown in FIG. 1B, with clips to secure the devices to the pallet. The pallet, in one embodiment, also includes a shelf, which is folded over, and fiducial markers, to provide positioning data for visual identification for positioning by the robotic cells. In one embodiment, the pallet is designed to securely support multiple device configurations for disassembly.

At block 320, the device barcode is scanned and stored. In one embodiment, each device has a barcode, which can be used to track the disassembly of the device through the microfactory line. In one embodiment, the provenance of the components can be tracked using the barcode as well, as will be described below.

In one embodiment, a session envelope is created when the device barcode is initially scanned. This session envelope travels with the pallet through the microfactory line, and is updated with the success or failure of each of the steps along the path. In one embodiment, the session envelope is initially created by a processor associated with the microfactory line based on the scanned barcode. In one embodiment, the session envelope is created automatically. It is then sent to the queue of the first robotic cell. When the pallet leaves the loading station, its session envelope is sent to the queue of the first station. When the pallet leaves the first robotic cell, the cell forwards the session envelope, now updated with the outcome of the actions at the first robotic cell, to the next robotic cell in the microfactory line. In another embodiment, a supervisory application may maintain the device status, and receive updates from each of the robotic cells as they process devices on a pallet.

At block 325, the vision system is used to verify the presence and position of devices on the pallet. In one embodiment, the robotic cell utilizes the vision system to verify the presence of the pallet, presence of the devices on the pallet, and the alignment of the devices on the pallet. In one embodiment, a machine learning algorithm is used to recognize the configuration of the device on the pallet and confirm the presence of the expected number and configuration of devices. In one embodiment, the machine learning system is a neural network based architecture. In one embodiment, the neural network is a convolutional neural network (CNN), trained with devices of various configurations on the pallets.

At block 330, the devices on the pallet are moved to the first robotic cell in the microfactory line. The session envelope, with the pallet data, is retrieved from the queue.

At block 335, the robotic cell performs the actions associated with the robotic cell. In one embodiment, the actions may be to remove the element, and place the removed element in a collection location. The collection location may be a tray or pallet, a container, a box, or another type of collection location. The session envelope is then updated with the results of the removal action. In one embodiment, if the removal is successful, the session envelope is updated indicating this. If the removal is not successful, in one embodiment, the session envelope is updated to indicate that a first attempt was not successful. This leaves the device with the indication that there is an element to be removed by this cell. In one embodiment, the system may re-try removing the element if it does not succeed in a first attempt. In one embodiment, each attempt is recorded in the session envelope.

At block 340, the process determines whether there are more elements for processing by this cell. If so, the process returns to block 335, to process the next element.

If there are no more elements to be processed by this cell, the process continues to block 350.

At block 350, the process determines whether there are more robotic cells in this microfactory line. If so, at block 355 the pallet is moved out of the robotic cell, and the session envelope is sent to the next station's queue. The process then continues to block 330, to move the device into the next robotic cell in the microfactory line.

If there are no more robotic cells in the microfactory, at block 360, the cleaned up device is moved to collections. The session envelope, with the report including the success or failure of each action by each robotic cell in the microfactory, associated with the device is completed. This enables tracking not only when there are devices with one or more remaining elements, but also the effectiveness of the disassembly process. In one embodiment, the system tracks the number of devices which indicate one or more failures. In one embodiment, if the number of failures is above a threshold, the system is recalibrated. In one embodiment, the system may be redesigned, to update a robotic cell, end of arm tool, and/or software process that causes failures.

In one embodiment, at collections the now-cleaned device(s) are removed from the pallet and placed in a collection location. In one embodiment, any devices that have one or more failures associated with their associated reports, may be separately further processed to either go through the process again, or manually complete the disassembly. In one embodiment, the removal of the processed devices from the pallet and their placement in the collection location is done manually. In another embodiment, the device removal may be automated. The process then ends at block 365.

The specific examples below are with respect to constructing a microfactory for disassembly of a server. However, one of skill of the art would understand that the same process may be used to construct a microfactory for disassembly of other systems, for example, a laptop, a gaming device, a desktop computer, a battery system, a lighting system, etc. The present system may be used for disassembly of any device in which components can be manually removed.

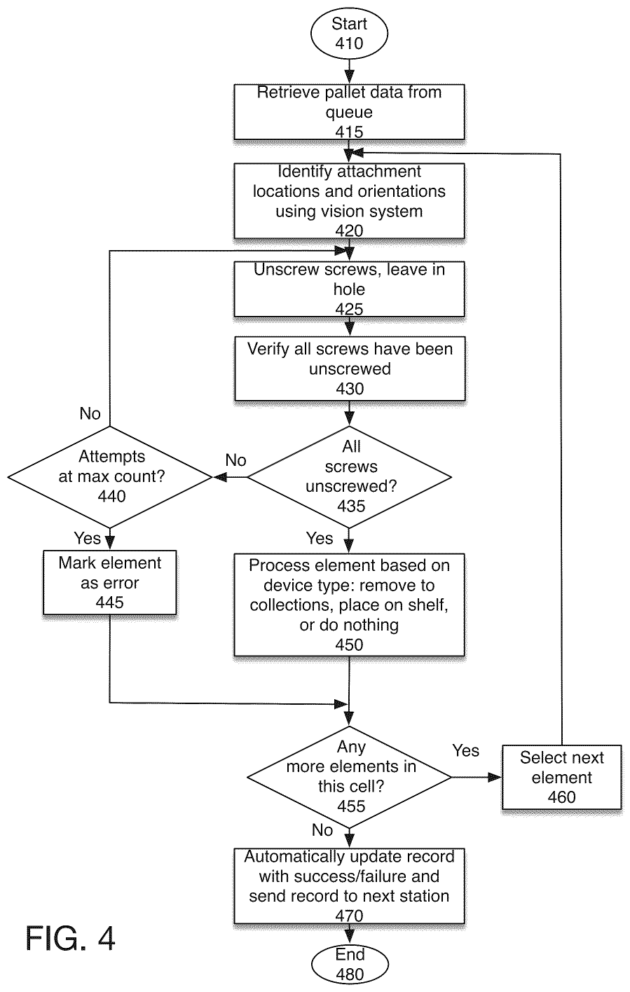

FIG. 4 is a flowchart of one embodiment of removing a heatsink. This is an exemplary process to show the flow for the removal of one kind of device. One of skill in the art would understand that a similar process may be applied for other components. The process starts at block 410.

At block 415, the pallet data is retrieved from the queue. The pallet data, as discussed above, includes a session envelope for each device on the pallet, and is used to track each stage of the disassembly, so at the end of the process the system has a record of every stage of the disassembly.

At block 420, the attachment locations and orientations are identified using the vision system. For a screwed-on heat sink this identifies screw locations and the orientation of the screw head (e.g. the angle of the slot(s) for a slotted screw head or Philips screw head. If the heatsink is attached by clips or pegs, the location and position of those clips or pegs are identified. In one embodiment, each of the screws of a heatsink are identified at this stage. In one embodiment, the system uses the vision system to locate fiducial on the pallet, the fiducial to locate the server board, the known configuration of the server board to locate the heatsink, and the known configuration of the heat sink to locate the attachment locations. The orientation is identified based on the visual data.

At block 425, the screwdriver end-of-arm tool is used to unscrew each of the screws. In one embodiment, this takes multiple actions: moving the screwdriver end of arm tool over the screw, aligning the screwdriver head to the orientation of the screw, lowering the screwdriver until it engages with the slot in the screw, and turning the screw. In one embodiment, the system configuration provides data about the length of the screws, and thus the number of turns to fully unscrew. In one embodiment, a sensor or camera is used to determine when the screw has been sufficiently loosened to enable removal of the heatsink. In one embodiment, a camera detects the height of the screw. The screws are left in the screw holes, in one embodiment. This reduces the number of steps to complete the heatsink removal. In another embodiment, the screws may be removed and discarded.

In one embodiment, the visual verification confirms that all of the screws have been successfully unscrewed, at block 430. In one embodiment, the system identifies orientation of the screws for this verification. Once loosened completely the screws are no longer aligned with the screw hole, and this can be visually identified.

At block 435, the process determines whether all the screws are unscrewed. If not, at block 440, the process determines whether the maximum number of attempts have been made. The system may, in one embodiment, attempt to unscrew each of the screws multiple times, if the first attempt is not successful. In one embodiment, three attempts may be made for each screw. In one embodiment, to make a new attempt, the robotic arm is placed in neutral position, and the process restarts at block 425, for the system to re-attempt the removal of the screw. In one embodiment, the visual evaluation of the screw positions and location (block 420) may also be reverified for a subsequent attempt. When the maximum number of attempts has been made, and the screws are not successfully unscrewed, the element is marked as faulty, at block 445. The process then continues to block 455.

If all screws are identified as successfully unscrewed, at block 435, the process continues to block 450. At block 450, the element is processed based on device type. In one embodiment, for one configuration the heatsink with its attached screws is removed into a collection location. In one embodiment, the collection location for the heatsink is a chute to deposit it into a collection box. For another device configuration, no action may be taken, and the unscrewed heatsink may remain on the device. For another device configuration, the heatsink with the attached CPU may be placed on the pallet shelf. The pallet shelf provides a secure location for the heatsink as the pallet moves to the next robotic cell, without risk that the screws reengage with the screw hole as the pallet is moved.

At block 455, the process determines whether there are more elements for removal by the robotic cell. If there are more elements for removal, the process at block 460 selects the next element, and the process returns to block 420 to visually locate the screws for the next element.

If there are no further elements in the cell, the session envelope record associated with the device is automatically updated with the success/failure of the removal process, at block 470. The session envelope is then sent to the next robotic cell's queue. The process ends at block 480.

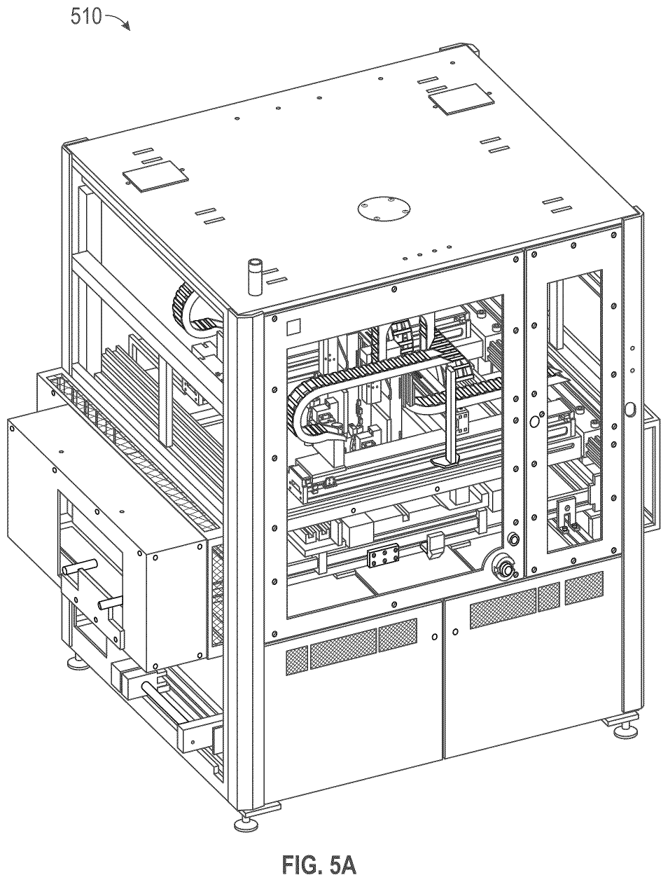

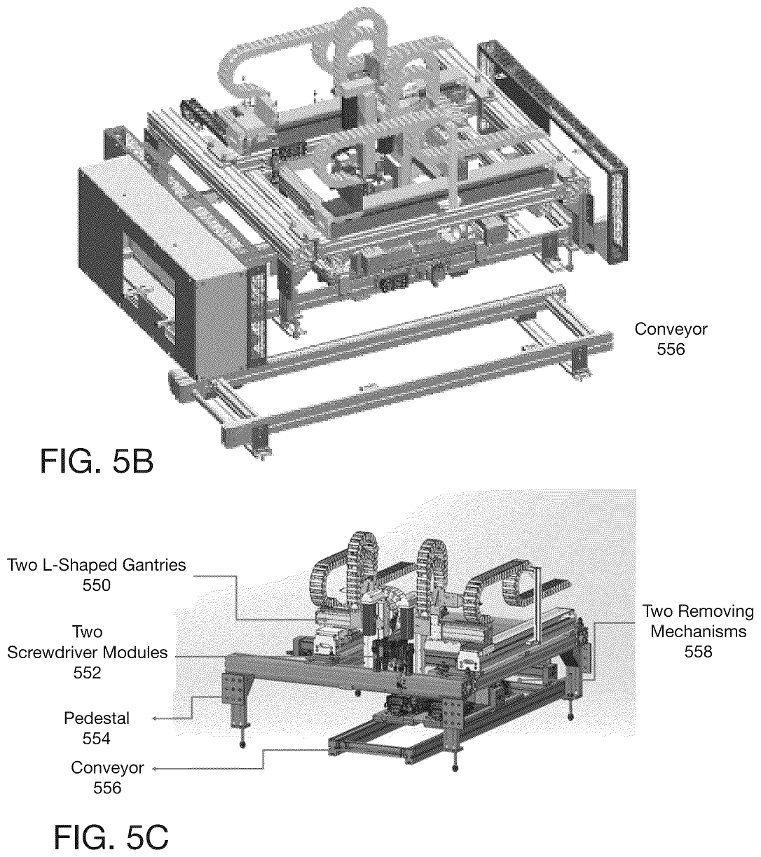

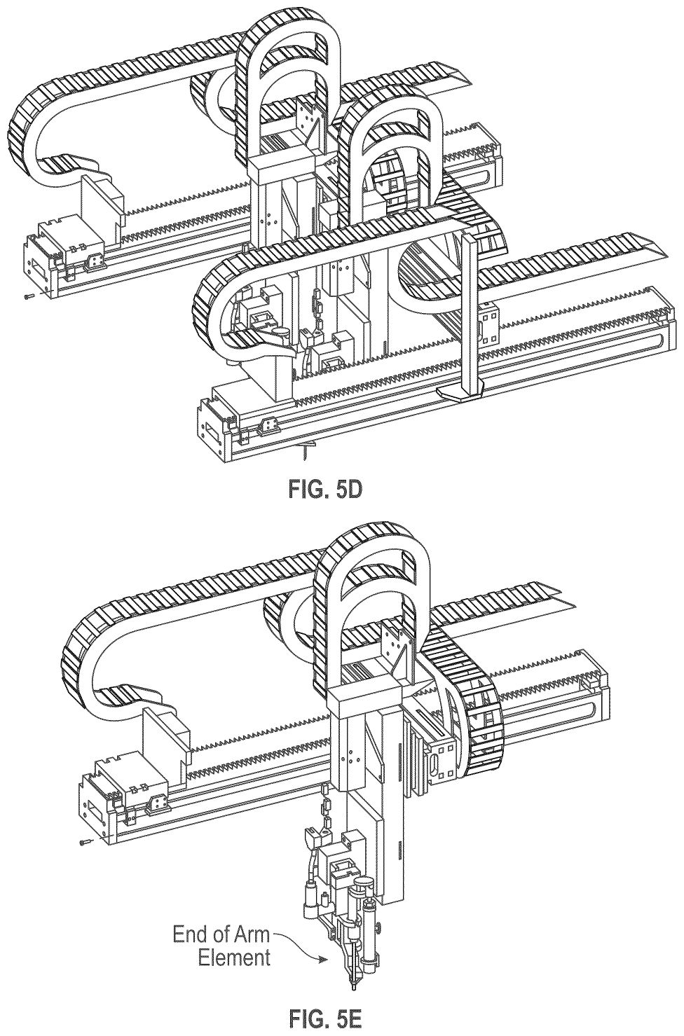

FIG. 5A-5E are diagrams of embodiments of the hardware configuration of the robotic cell for the heatsink removal. The hardware configuration in one embodiment includes the robotic cell 510 shown in FIG. 5A, which has a pair of L-shaped gantries 550, shown in FIG. 5B. FIG. 5C illustrates the pair of L-shaped gantries 550, screwdriver modules 552, and removing mechanisms in more detail. The L-shaped gantry covers a partial left or right volume of the robotic cell, enabling two arms, and simultaneous processing of two devices, without collision. In one embodiment, each side gantry covers symmetrically half of the robotic cell with no common area, which physically prevents any collision between the two side gantries. The L-shaped gantries provide movement of the end of arm element holding the screwdriver to the appropriate position to remove the screws fastening a heat sink, in one embodiment. In one embodiment, the two gantries enable the removal of heat sinks on both of the devices on a pallet simultaneously. FIG. 5D illustrates a side perspective view of the double L gantries, while FIG. 5E illustrates a single L-shaped gantry, including the end-of-arm element.

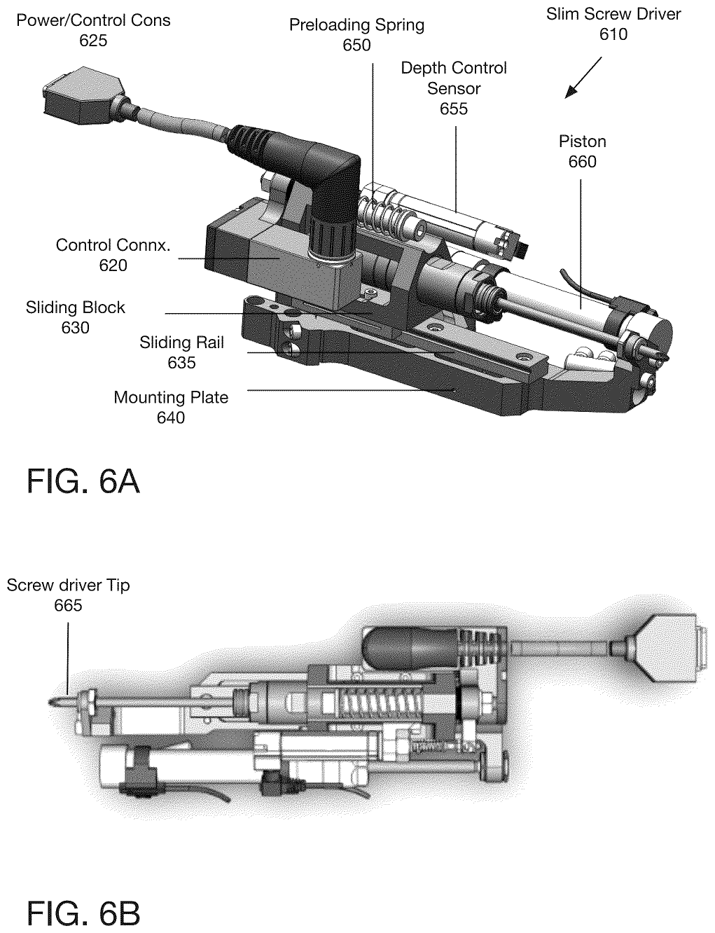

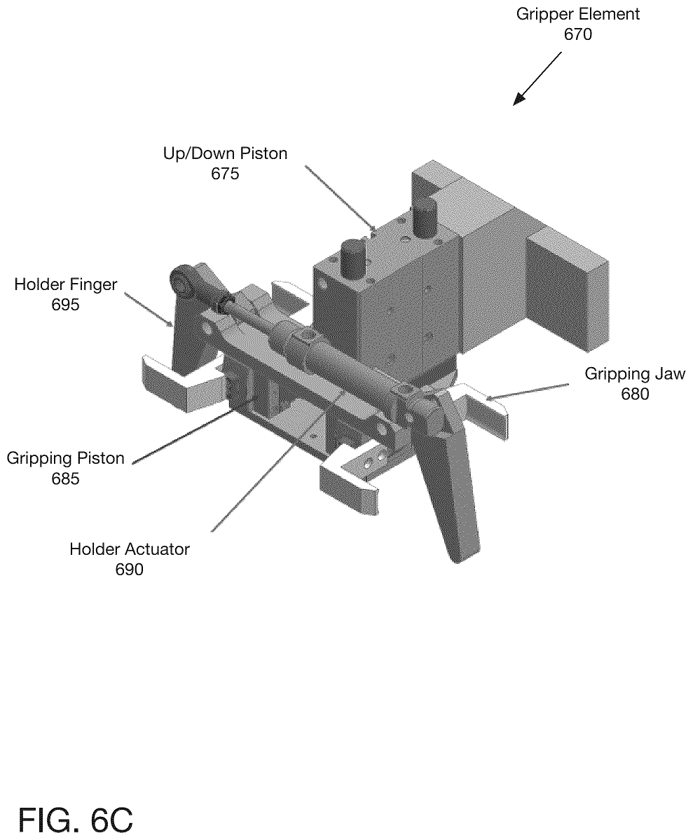

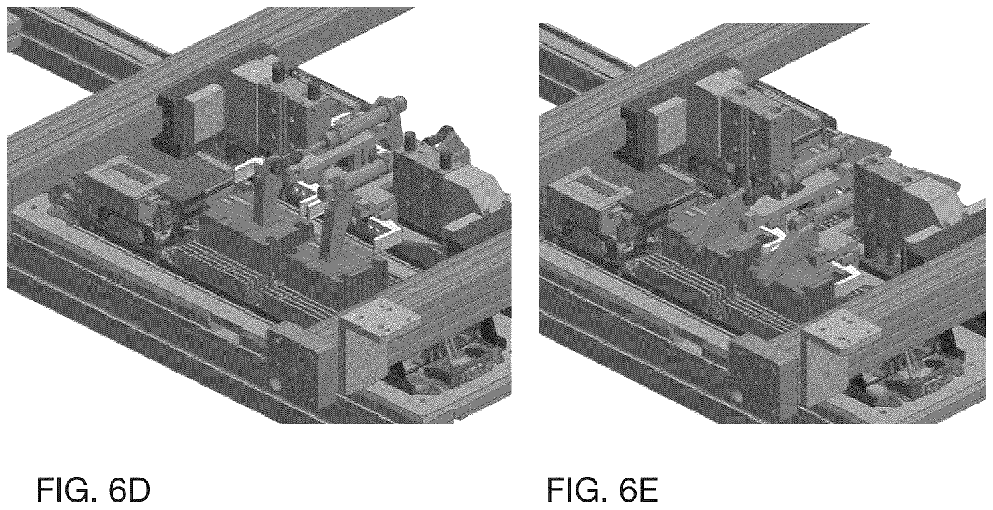

FIGS. 6A-6E are diagrams of embodiments of the end of arm elements for the heatsink removal. FIGS. 6A and 6B illustrate one embodiment of the slim screwdriver structure 610. As can be seen, in this embodiment the screwdriver 610 includes a connector 625, and hydraulic to lower the screwdriver, using sliding rail 635 and insert the screwdriver tip 665 into the screw head. The screwdriver 610 has a narrow design to enable the positioning of two screw drivers within the robotic cell.

FIG. 6C illustrates one embodiment of the gripper element. In one embodiment, the gripper element holds the heatsink while it is being unscrewed, and removes the heatsink, to place it in the collection area.

In one embodiment, the gripper element includes a holder finger 695, to stabilize the heatsink while it is being unscrewed. In one embodiment, the use of the holder finger 695 depends on the type of attachment mechanism of the heatsink. By holding the heatsink stable, the system ensures that the screws already loosened do not reengage due to the vibration of the heatsink. However, for a spring-loaded heatsinks the holder causes issues with unscrewing. Therefore, part of the configuration of the removal system is determining how the heatsinks are attached and determining whether to use the holder finger.

The gripping jaws 680 are used to grab the heatsink once it is unscrewed and move them to the disposal position. In one embodiment, the gripper element 670 as shown can simultaneously hold and grip two heatsinks, one on either side of the gripper element 670.

FIGS. 6D and 6E illustrate the holder fingers of the gripper element of FIG. 6C in action. As can be seen, the holder fingers stabilize the heatsinks while the screwdrivers are working. Once the screws are successfully loosened, the holder fingers move out of the way, and the gripper jaws are used to grab and lift the heatsinks off the server device.

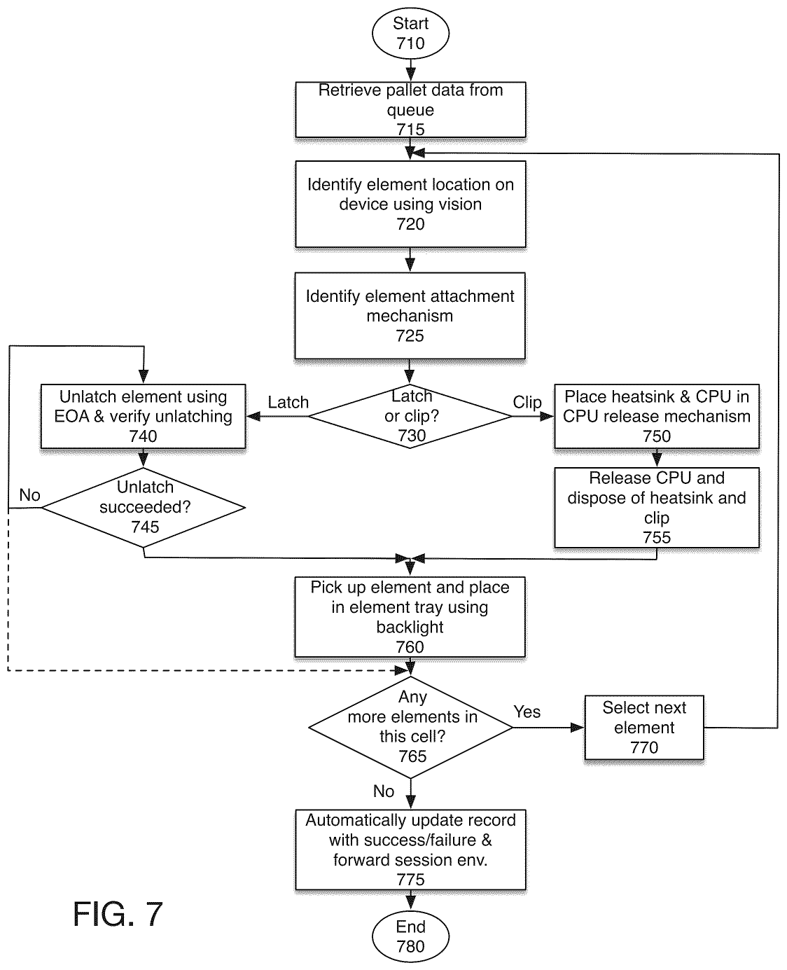

FIG. 7 is a flowchart of one embodiment of removing the central processing unit (CPU). The process starts at block 710.

At block 715, the pallet data for the current pallet is retrieved from the queue. The pallet data is the session envelope associated with each device on the pallet, and is used to track the success or failure of each of the removal steps.

At block 720, the element location is identified, using vision analysis. In one embodiment, the CPU element has various shapes and configurations, based on the specific server being disassembled.

At block 725, the attachment mechanism for the CPU is identified. In one embodiment, the attachment mechanism may be a latch, latching the CPU to the motherboard, or a clip, clipping the CPU to a heatsink. At block 730, the process determines whether the attachment mechanism is a latch or clip. In another embodiment, a different type of attachment mechanism may be identified.

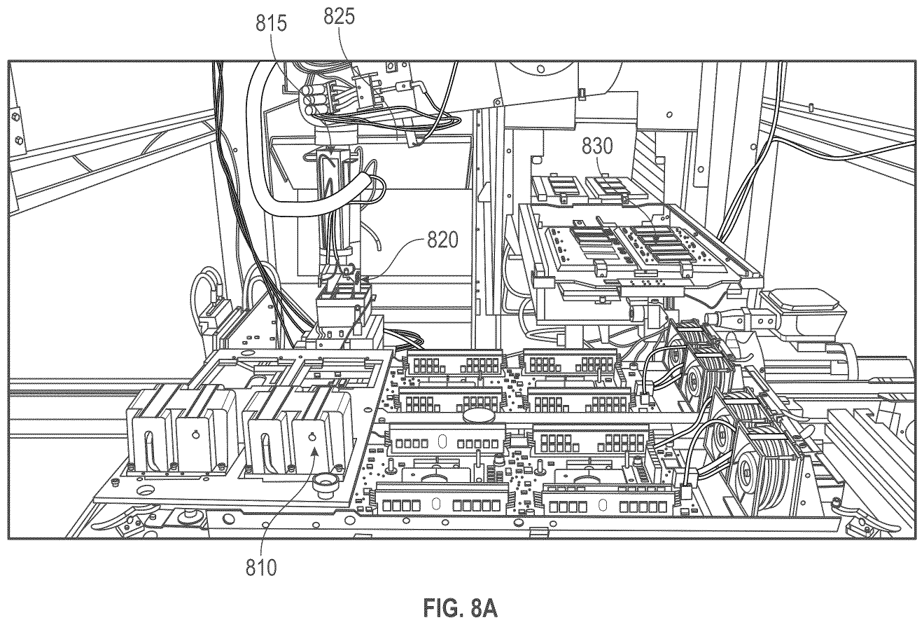

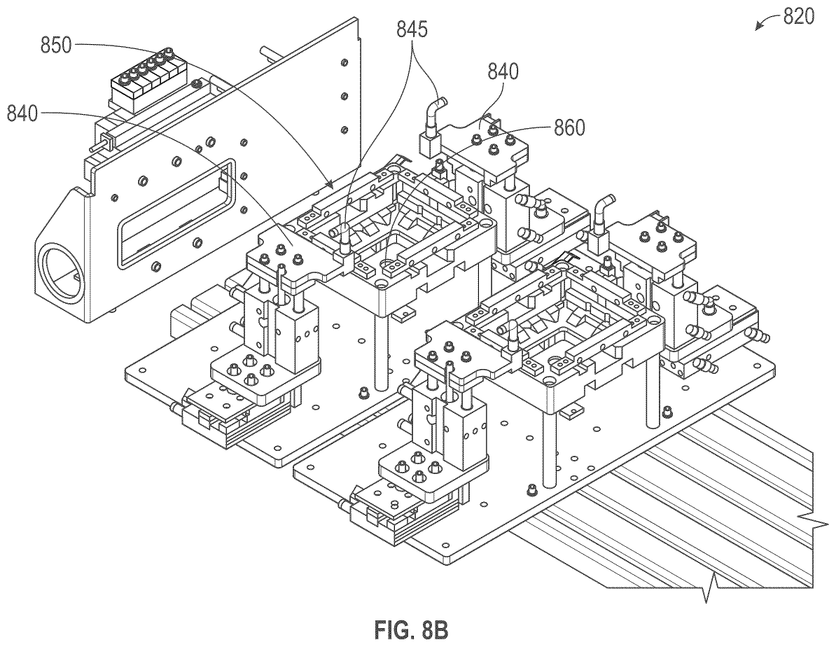

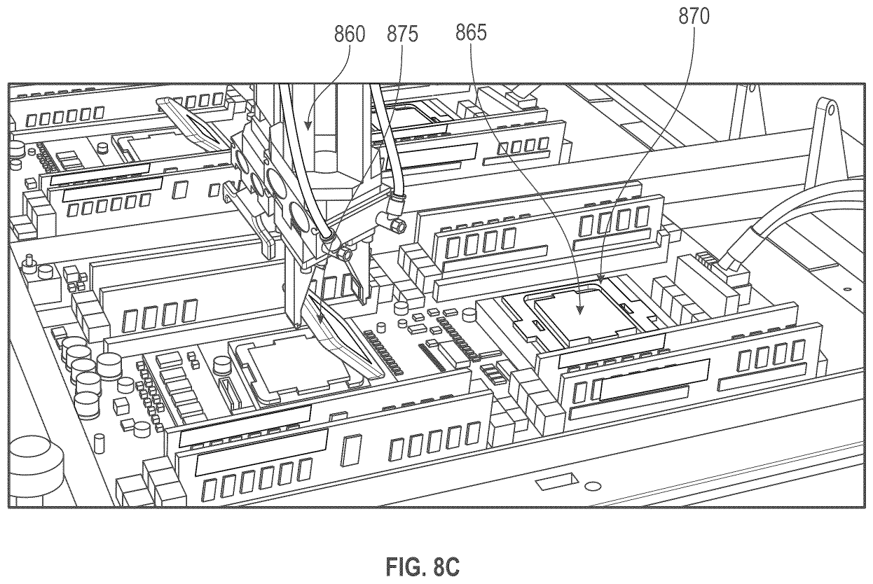

If the attachment mechanism is a latch, at block 740 the end of arm tool is used to unlatch the element from the board. In one embodiment, an unlatching dance utilizes a multistep process to open a latch or other connector. For example, for some CPU configurations, a three-stage latch may be used in which a latch initially is unlocked, and then lifted, before the CPU can be removed. FIG. 8C illustrates such a latch being opened. The unlatching is verified, using visual analysis. At block 745, the process determines whether the unlatching succeeded. If so, the process continues to block 760. If the unlatching did not succeed in one embodiment, the system attempts unlatching again. In one embodiment, if the unlatching fails after multiple attempts, the record is updated indicating failure to remove the CPU, and the process continues to block 765 to determine whether there are more elements for removal.

If, at block 730, the process determined that the attachment was a clip to a heatsink, the process continues to block 750. At block 750, the heatsink with its attached CPU are placed in a CPU release mechanism. In one embodiment, the heatsink and CPU are moved from the pallet shelf, where they were placed during the heatsink removal process, described above.

At block 755, the CPU is separated from the heatsink. In one embodiment, side pistons are used to dislodge the CPU, and a detector is used to detect when the separation is successful. Once the CPU is released, the heatsink and the clip are disposed of. In one embodiment, the heat sink is placed in a first collection location, and the clip in a separate collection location. The process then continues to block 760.

At block 760, the released CPU is picked up and placed in a collection tray. In one embodiment, the element in the CPU release mechanism is picked up with special CPU-grippers, which are part of the end-of-arm tool. In one embodiment, a light is used to light the collection tray from below to enable correct placement of the CPU in the tray.

At block 765, the process determines whether there are more elements in this cell. If so, the next element is selected at block 770, and the process returns to block 720. Otherwise, at block 775, the record associated with the pallet data is updated with the success/failure of the removal process, and the session envelope is sent to the next robotic cell in the microfactory line. The process then ends at block 780. This process, in one embodiment, is used to remove a CPU. But of course, it could also be applied to remove any other element which is attached by a latch or clip.

FIG. 8A illustrates one embodiment of the robotic cell including a pallet, and a CPU separation unit, into which a CPU with an attached heatsink is placed to separate the elements. FIG. 8A illustrates the CPUs 810, with the robotic arm 815 placing a CPU with attached heatsink in the CPU separation unit 820. Once the CPU is separated from the heatsink, the heatsink and attachment bracket are placed in the disposal chute 825, and the CPU is moved to the storage tray 830, which in one embodiment is underlit for placement.

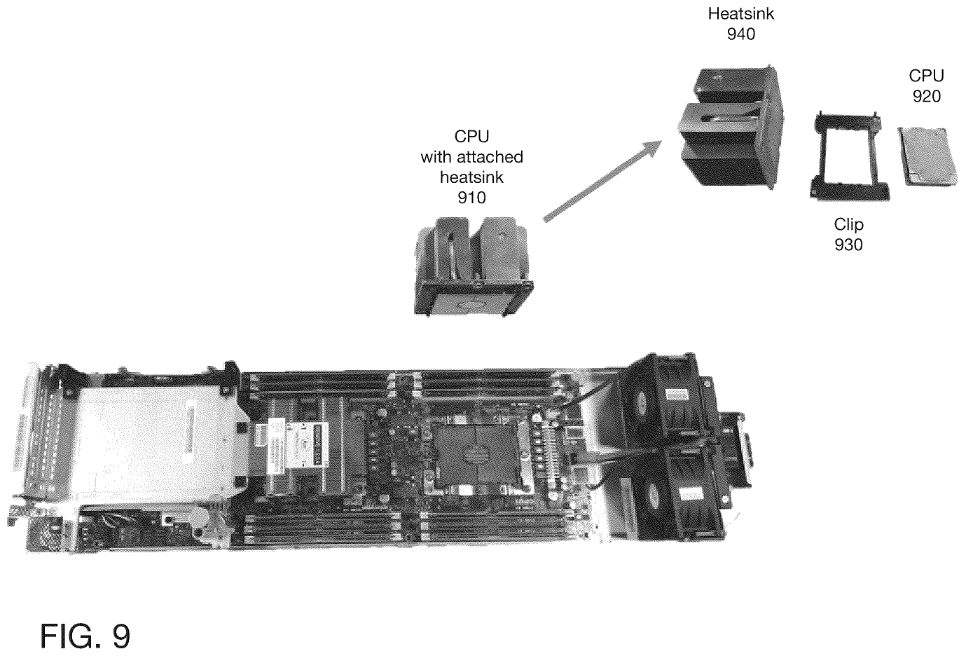

FIG. 8B is a diagram of one embodiment of a CPU separation unit. The CPU separation unit includes a bracket 850 into which the CPU with the attached heatsink is placed. The CPU is attached to the base of the heatsink with a plastic clip, in one embodiment, when it is loaded to the CPU separation unit 820. FIG. 9 illustrates one embodiment of the three parts of the CPU, including the CPU with attached heatsink 910, and then illustrating the separated parts of the CPU 920, clip 930, and heatsink 940.

The side pistons 840 tap the elements in the bracket 850 to separate the heatsink, the clip, and the CPU. Then, the hammer piston 845 pushes the clip and the CPU away from the heatsink until the CPU presence sensor 860 indicates the separation happened. In one embodiment, the CPU presence sensor 860 is a proximity sensor, detecting when the CPU has dropped into the sensor area. In one embodiment, the robot end of arm is holding the heatsink during this process, and when separation is sensed, the end of arm lifts the heatsink, now without the CPU, and places it in the chute. After that, the robot EOA separates the clip from the CPU, and disposes of the clip to another chute. The robot end of arm then lifts the CPU from the CPU separation unit 820, and places it in the tray.

FIG. 8C is an illustration of one embodiment of the CPU clip being opened by the end of arm tool. In one embodiment, the robot end of arm 880 first opens the CPU clip lever 870, then opens the clip frame 875, freeing the CPU 865 for removal.

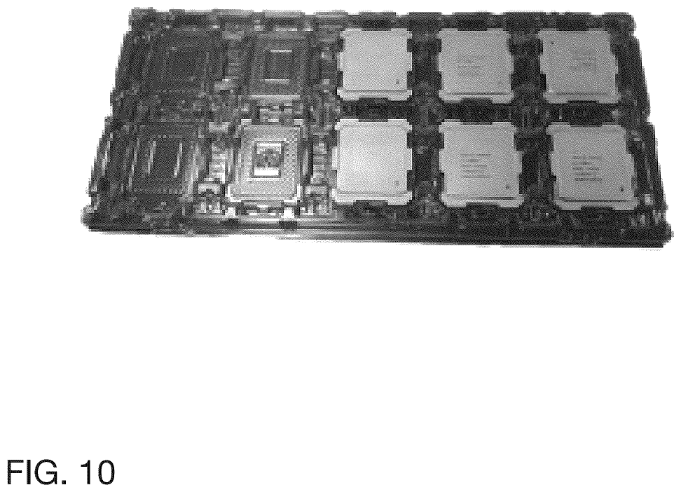

FIG. 10 is an illustration of one embodiment of the tray into which the CPU is placed after removal. The tray in one embodiment is made of translucent plastic and is lit from below to ensure correct positioning of the CPUs within a compartment. The end of arm tool places the CPU in the tray after removal.

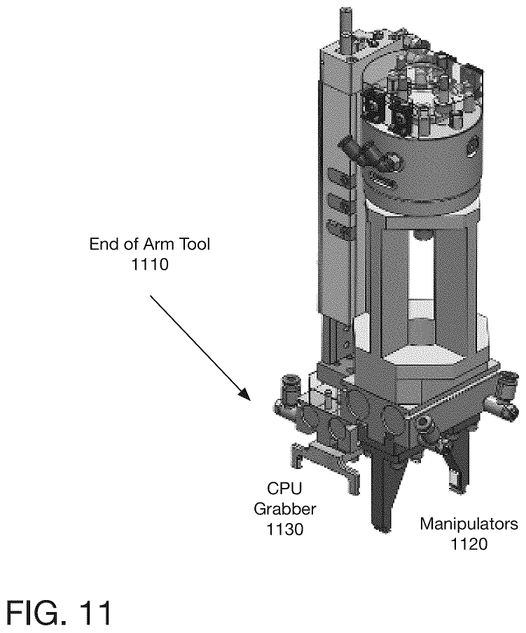

FIG. 11 is a diagram of one embodiment of the end of arm configuration for the CPU removal. In one embodiment, the end of arm tool 1110 has 360 degrees of movement and includes manipulators 1120, and CPU grabber 1130. In one embodiment, for some uses, the CPU grabber 1130 may be used, rather than the manipulator 1120. For example, in one embodiment, the CPU grabber may be used to remove the CPU from the CPU separation unit, because that enables using a tighter tolerances, because the CPU grabber 1130 has thinner tines. In another embodiment, the manipulator may be used for each step. The manipulator may be used for picking up the heatsink combined with the CPU, as well as for unlatching a CPU latch. The end of arm configuration can support a variety of types of CPU attachment mechanisms.

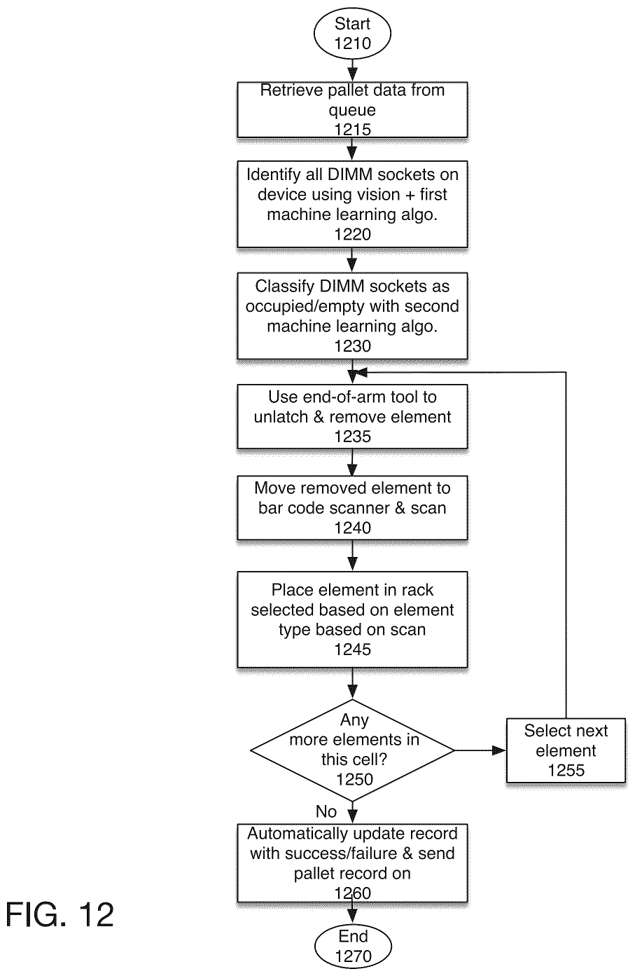

FIG. 12 is a flowchart of one embodiment of the memory module (DIMM) removal. The process starts at block 1210.

At block 1215, the pallet data for the pallet is retrieved from the queue. The pallet data, or session envelope, is used to track the success or failure of each element of the removal process.

At block 1220, the DIMM sockets on the device are identified using vision analysis. In one embodiment, a machine learning algorithm is used to detect the DIMM sockets. In one embodiment, the machine learning algorithm is trained on detecting DIMM latches, and utilizes vision analysis of the expected locations of the DIMM sockets on the server layout, to identify DIMM sockets. In one embodiment, if the DIMM removal is split over multiple robotic cells, the system only identifies DIMM sockets on one side, or one portion, of the server board. In one embodiment, the camera configuration in the robotic cell may be based on the actions assigned to the robotic cell. For example, in some embodiments, the cameras or other sensors may be directed to a portion of the workspace of the robotic cell where the DIMMs (or CPU, or heatsinks) are located.

At block 1230, the DIMM sockets are classified as occupied or empty. In one embodiment, a second machine learning algorithm is used for classification. In one embodiment, the classification is based on determining whether the latches are open or closed. Once the occupied DIMM sockets are identified, the system starts the removal process to remove the DIMMs from the occupied slots.

At block 1235, the end of arm tool is used to unlatch the DIMM slot, and remove the DIMM.

At block 1240, the removed element is moved in front of a bar code scanner, and scanned. This allows separation of elements by type. For example, DIMM modules may be different sizes, configurations, and/or have different storage capacities. In another embodiment, the barcode scanner may be replaced by a camera, to detect the size indication or number of memory chips on the DIMM module.

At block 1245, the element is placed in a collection rack based on the bar code scan results. In one embodiment, the system may separate out DIMMs (or other elements) by memory storage size, and/or physical size.

At block 1250, the process determines whether there are more elements for removal in this cell. If so, at block 1255, the next element is elected, and the process returns to block 1235 to remove the next element. If there are no more elements for removal, at block 1260, the record associated with the device is updated with the success or failure of the removals. The process then ends at block 1270. This process, in one embodiment, is used to remove DIMMs. But of course, it could also be applied to remove any other element which is removed from a socket.

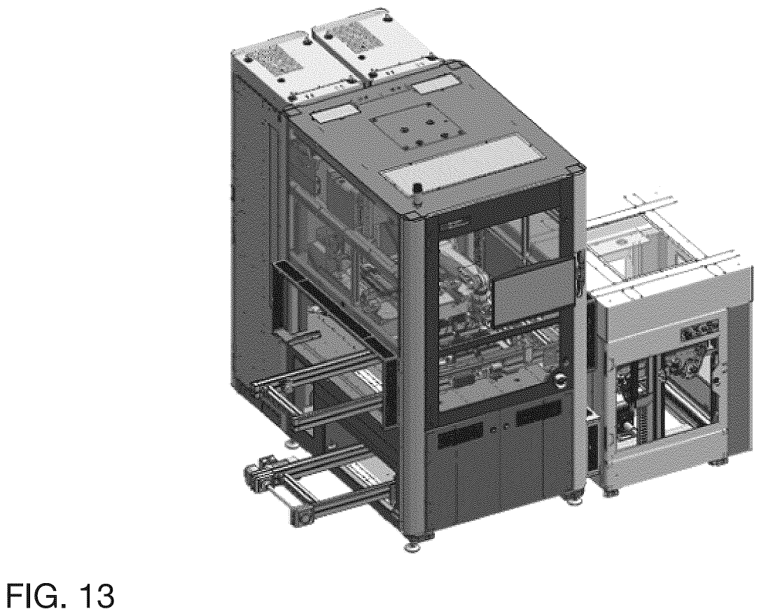

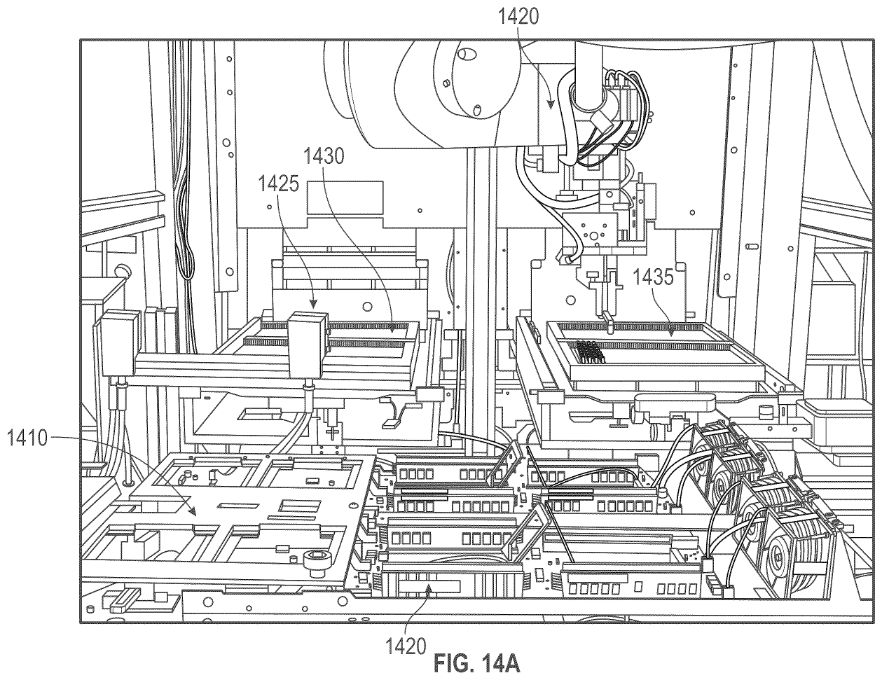

FIG. 13 is a diagram of one embodiment of the hardware configuration of the robotic cell for the DIMM removal.

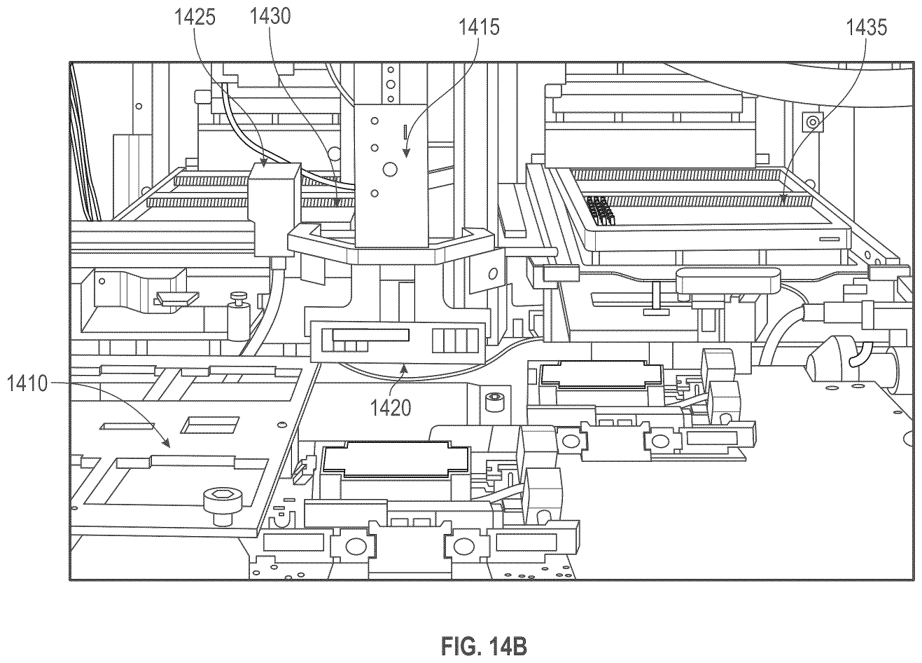

FIG. 14A illustrates one embodiment of the robotic cell from the DIMM removal. The pallet 1410 including a plurality of DIMMs enters the robotic cell. the robotic arm 1415 opens a DIMM latch and removes a DIMM module 1420. It then moves in front of the barcode reader 1425. The barcode reader 1425 reads the barcode on the DIMM, and instructs the robotic arm 1415 to place the DIMM module into either the first tray 1430 or the second tray 1435. The robotic arm moves to the appropriate tray, and places the DIMM module into the tray. In this way, the DIMM modules are sorted automatically.

FIG. 14B illustrates an embodiment of the DIMM module remover cell, with the robotic arm 1415 holding a DIMM module 1420, that has just been removed from the server on pallet 1410. The robotic arm 1415 will then move the removed DIMM module in front of the barcode reader 1425, as discussed above.

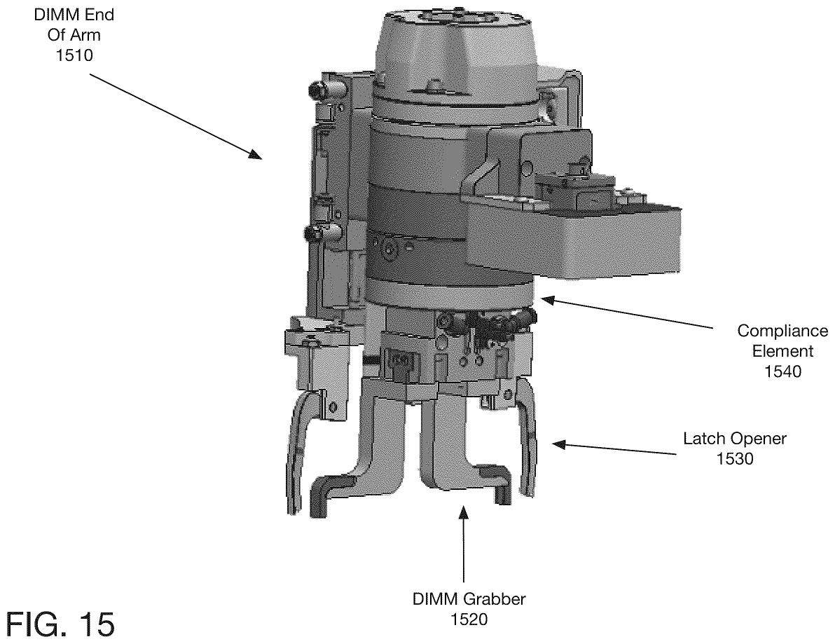

FIG. 15 is a diagram of one embodiment of the end of arm element configuration for the DIMM removal. The end-of-arm 1510 moves up and down on a robotic arm. The end of arm 1510 includes a DIMM grabber 1520, and a latch opener 1530. The latch opener 1530 is initially lowered to open the DIMM latches. Once the latches are open, in one embodiment verified visually, the DIMM grabber 1520 is opened, and closes around the DIMM, to lift it out of the socket. The DIMM grabber 1520 in one embodiment has shaped tines, to fit around the edge of the module. The compliance element 1540 provides lateral shifting to the latch opener 1530 and DIMM grabber 1520, to account for slight shifts in position.

The processes described above are described specifically with respect to disassembly of a server including one or more heatsinks, CPUs, and DIMMs (collectively, elements) which are removed from the server (device). However, one of skill in the art would understand that the same processes may be used to remove other components from a server device or disassemble other types of devices. In one embodiment, the end of arm tools are robotic cells are reconfigurable, to accommodate different devices and different removal techniques. For example, the unscrewing and removing to a disposal chute may also be used to remove a fan or another element.

In one embodiment, the microfactory disassembly system provides a quickly reconfigurable disassembly line, to enable recycling and reusing of electronic components. In one embodiment, a particular microfactory line may be designed to handle a variety of compatible devices, such as a variety of servers, without hardware reconfiguration. This enables processing assorted devices, in one embodiment. In another embodiment, this enables rapid switchover, with only a software adjustment, and no change to the microfactory line or end of arm tools. This enables the system to be more flexible. Furthermore, instead of requiring weeks to construct a disassembly line, the modularity and adjustability of the robotic cells making up the microfactory enables the present system to be made ready to disassembly a variation on existing devices in minutes to hours, instead of weeks to months. The microfactory may be redesigned to disassembly entirely new devices in weeks instead of months or years. In this way, the present system makes recycling and reuse of electronic components more cost effective and available.

In the figures above which are shown as flowcharts, in one embodiment the order of operations is not constrained to the order illustrated, unless the processes are dependent on each other. Furthermore, in one embodiment the system may be implemented as an interrupt-driven system, and thus the system does not check for the occurrence, but rather the occurrence sends a notification to trigger actions. Thus the “decision blocks” may be implemented as any time of monitoring system that permits the system to determine whether something occurred/has a particular value/etc.

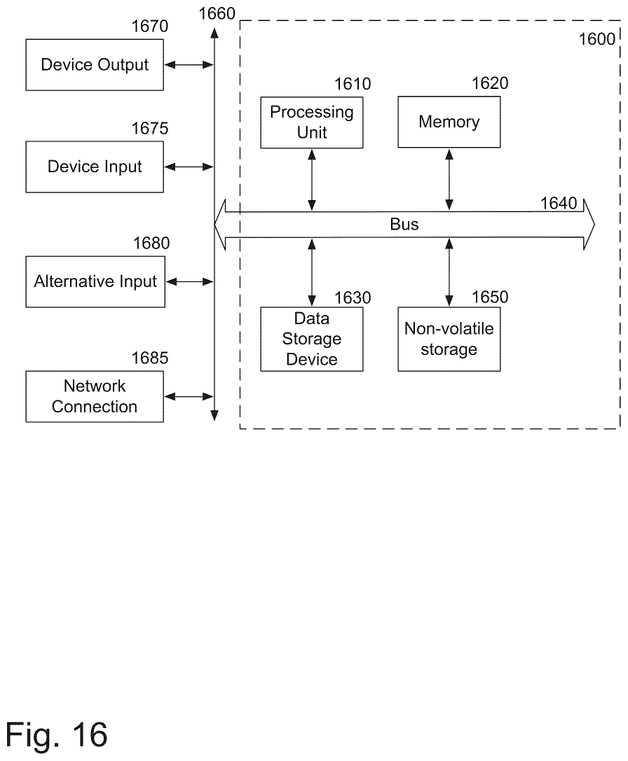

FIG. 16 is a block diagram of one embodiment of a specific purpose computer system. It will be apparent to those of ordinary skill in the art, however that other alternative systems of various system architectures may also be used.

The computer system illustrated in FIG. 16 includes a bus or other internal communication means 1640 for communicating information, and a processing unit 1610 coupled to the bus 1640 for processing information. The processing unit 1610 may be a central processing unit (CPU), a digital signal processor (DSP), graphics processor (GPU), or another type of processing unit 1610.

The system further includes, in one embodiment, a memory 1620, which may be a random access memory (RAM) or other storage device 1620, coupled to bus 1640 for storing information and instructions to be executed by processor 1610. Memory 1620 may also be used for storing temporary variables or other intermediate information during execution of instructions by processing unit 1610.

The system also comprises in one embodiment a read only memory (ROM) 1650 and/or static storage device 1650 coupled to bus 1640 for storing static information and instructions for processor 1610.

In one embodiment, the system also includes a data storage device 1630 such as a magnetic disk or optical disk and its corresponding disk drive, or Flash memory or other storage which is capable of storing data when no power is supplied to the system. Data storage device 1630 in one embodiment is coupled to bus 1640 for storing information and instructions.

In some embodiments, the system may further be coupled to an output device 1670, such as a computer screen, speaker, or other output mechanism coupled to bus 1640 through bus 1660 for outputting information. The output device 1670 may be a visual output device, an audio output device, and/or tactile output device (e.g., vibrations, etc.)

An input device 1675 may be coupled to the bus 1660. The input device 1675 may be an alphanumeric input device, such as a keyboard including alphanumeric and other keys, for enabling a user to communicate information and command selections to processing unit 1610. An additional user input device 1680 may further be included. One such user input device 1680 is cursor control device 1680, such as a mouse, a trackball, stylus, cursor direction keys, or touch screen, may be coupled to bus 1640 through bus 1660 for communicating direction information and command selections to processing unit 1610, and for controlling movement on display device 1670.

Another device, which may optionally be coupled to computer system 1600, is a network device 1685 for accessing other nodes of a distributed system via a network. The communication device 1685 may include any of a number of commercially available networking peripheral devices such as those used for coupling to an Ethernet, token ring, Internet, or wide area network, personal area network, wireless network, or other method of accessing other devices. The communication device 1685 may further be a null-modem connection, or any other mechanism that provides connectivity between the computer system 1600 and the outside world.

Note that any or all of the components of this system illustrated in FIG. 16 and associated hardware may be used in various embodiments of the present invention.

It will be appreciated by those of ordinary skill in the art that the particular machine that embodies the present invention may be configured in various ways according to the particular implementation. The control logic or software implementing the present invention can be stored in main memory 1620, mass storage device 1630, or other storage medium locally or remotely accessible to processor 1610.

It will be apparent to those of ordinary skill in the art that the system, method, and process described herein can be implemented as software stored in main memory 1620 or read only memory 1650 and executed by processor 1610. This control logic or software may also be resident on an article of manufacture comprising a computer readable medium having computer readable program code embodied therein and being readable by the mass storage device 1630 and for causing the processor 1610 to operate in accordance with the methods and teachings herein.

The computer system 1600 may be used to program and configure the robotic cells and provide instructions to the robotic arm. The computer system 1600 is also part of each robotic cell, enabling the robotic cell to execute instructions received in a recipe. The robotic cell is a special purpose appliance including a subset of the computer hardware components described above. For example, the appliance may include a processing unit 1610, a data storage device 1630, a bus 1640, and memory 1620, and no input/output mechanisms, except for a network connection to receive the instructions for execution. In general, the more special purpose the device is, the fewer of the elements need be present for the device to function. In some devices, communications with the user may be through a touch-based screen, or similar mechanism. In one embodiment, the device may not provide any direct input/output signals, but may be configured and accessed through a website or other network-based connection through network device 1685.

It will be appreciated by those of ordinary skill in the art that any configuration of the particular machine implemented as the computer system may be used according to the particular implementation. The control logic or software implementing the present invention can be stored on a machine-readable medium locally or remotely accessible to processor 1610. A machine-readable medium includes any mechanism for storing information in a form readable by a machine (e.g., a computer). For example, a machine readable medium includes read-only memory (ROM), random access memory (RAM), magnetic disk storage media, optical storage media, flash memory devices, or other storage media which may be used for temporary or permanent data storage. In one embodiment, the control logic may be implemented as transmittable data, such as electrical, optical, acoustical, or other forms of propagated signals (e.g., carrier waves, infrared signals, digital signals, etc.).

Furthermore, the present system may be implemented on a distributed computing system, in one embodiment. In a distributed computing system, the processing may take place on one or more remote computer systems from the location of an operator. The system may provide local processing using a computer system 1600, and further utilize one or more remote systems for storage and/or processing. In one embodiment, the present system may further utilize distributed computers. In one embodiment, the computer system 1600 may represent a client and/or server computer on which software is executed. Other configurations of the processing system executing the processes described herein may be utilized without departing from the scope of the disclosure.

In the foregoing specification, the present system has been described with reference to specific exemplary embodiments thereof. It will, however, be evident that various modifications and changes may be made thereto without departing from the broader spirit and scope of the disclosure as set forth in the appended claims. The specification and drawings are, accordingly, to be regarded in an illustrative rather than a restrictive sense.

We claim:

1. A method to configure a microfactory line for disassembly of a device comprising:
designing a microfactory line comprising:
identifying a configuration of the device for disassembly;
determining each task to remove one or more components on the device, each task comprising one or more actions;
determining an order of the tasks based on the configuration of the device;
laying out the microfactory line including one or more robotic cells coupled by conveyors, each robotic cell to execute one or more of the actions, the microfactory to remove all components identified by the configuration, the microfactory including a collection location for each element removed from the device during the disassembly, and for the device; and
operating the microfactory line comprising:
receiving a new device;
automatically identifying the components for removal on the new device; and
automatically disassembling the new device by removing the components.

2. The method of claim 1, further comprising:
calculating time for the actions; and
determining that a task should be split between two robotic cells, when the time for the actions; and
adding an extra robotic cell for the task, such that the task is executed by two robotic cells.

3. The method of claim 2, wherein the task is split by one of:
having each of the two robotic cells execute a subset of the actions; and
having each of the robotic cells execute all of the actions, and routing some of the devices to a first one of the robotic cells and some of the devices to a second one of the robotic cells.

4. The method of claim 1, wherein the device comprises a server, and the tasks comprise removing one or more of: a heatsink, a memory module, and a processor.

5. The method of claim 1, wherein operating the microfactory line further comprises, for each robotic cell in the microfactory line:
receiving a pallet including the new device and a record for the new device;
executing one or more actions, to remove a component from the new device;
verifying the one or more actions; and
updating the record with a result of the one or more actions.

6. The method of claim 1, wherein the designing the microfactory line comprises:
receiving a target list of a plurality of devices, each of the plurality of devices having a compatible joint design with variations; and
identifying end-of-arm (EoA) tools for each of the tasks that are compatible with the compatible joint design of the plurality of devices; and
wherein the order of the tasks based is based on the compatible joint design, such that the microfactory line is configured to operate on any of the plurality of devices sharing the compatible joint design.

7. The method of claim 1, wherein a task comprises removing a heat sink, and the removing of the heat sink task comprises:
identifying positions of a plurality of screws holding the heat sink to the device;
stabilizing the heat sink with a holding finger, and unscrewing each of the plurality of screws; and
removing the heat sink.

8. The method of claim 7, further comprising:
when a central processing unit (CPU) is coupled to the heat sink, placing the heat sink into a pallet shelf on a pallet holding the device.

9. The method of claim 8, further comprising in a robotic cell for removing the CPU:
placing the heat sink with a CPU into a CPU separation unit;
using a hammer piston to push the CPU away from the heat sink;
receiving a signal from a CPU presence signal indicating that the CPU is separated from the heat sink; and
disposing of the heat sink and the CPU.

10. The method of claim 1, wherein a task comprises removing a memory module, and the removing of the memory module task comprises:
identifying one or more memory module sockets;
determining which of the one or more memory module sockets are occupied;
unlatching a first occupied memory module socket, and removing the memory module; and
repeating the process until all memory modules are removed.

11. The method of claim 10, further comprising:
scanning a removed memory module;
classifying the removed memory module based on the scanning; and
placing the removed memory module at an appropriate collection location based on the classification.

12. The method of claim 1, further comprising:
designing a common support pallet, the common support pallet used to move one or more devices on the conveyors, the common support pallet including a fiducial.

13. A method to disassemble of a device using a robotic cell comprising:
receiving a pallet supporting one or more devices at the robotic cell;
retrieving a record for the device;
utilizing vision processing to identify a component for removal from the device;
utilizing an end-of-arm tool to execute a plurality of actions to remove the component from the device;
utilizing the vision processing to verify a result of the plurality of actions;
updating the record for the device with the result; and
moving the device to a next robotic cell.

14. A microfactory to disassemble a device, the microfactory comprising a plurality of robotic cells, each robotic cell to take one or more actions to disassembly the device, the microfactory comprising:
a sensor to identify a device on a pallet;
a processor to generate a session envelope for the device prior to disassembly, the session envelope configured to be updated by each of the plurality of robotic cells with a result of the actions taken by the robotic cells;
a first robotic cell to receive the device on the pallet, retrieve the session envelope for the device, and:
use a vision system to identify a configuration of a component for removal;
use an end-of-arm tool to take the one or more actions to remove the component;
use the vision system to verify a result of the one or more actions; and
update the session envelope for the device;
wherein the plurality of robotic cells are used to remove designated components from the device.

15. The microfactory of claim 14, wherein the first robotic cell comprises a robotic cell to remove a heat sink from the device, the microfactory further comprising:
a screwdriver end-of-arm tool to loosen screws attaching the heat sink to the device;
a holder finger to stabilize the heat sink while the screwdriver end-of-arm tool is working;
the vision system to verify that all screws have been loosened; and
a grabber to remove the heat sink, after the verification by the vision system.

16. The microfactory of claim 15, further comprising:
moving the heat sink coupled to a central processing unit (CPU) to a shelf on the pallet.

17. The microfactory of claim 14, wherein the first robotic cell comprises a robotic cell to remove a CPU from the device, the microfactory further comprising:
a CPU separation unit configured to receive a heat sink with an attached CPU;
a hammer piston configured to push the CPU away from the heat sink in the CPU separation unit;
a CPU presence sensor to detect when the CPU is separated from the heat sink; and
an end-of-arm grabber to place the CPU into a collection location.

18. The microfactory of claim 17, further comprising:
an under-lit collection tray in the collection location, the under-lighting enabling placement of the CPU into the collection tray.

19. The microfactory of claim 14, wherein the first robotic cell comprises a robotic cell to remove a memory module from the device, the microfactory further comprising:
the vision system to identify one or more memory module sockets;
a processing system to determine which of the one or more memory module sockets are occupied based on data from the vision system;
the end-of-arm tool configured to unlatch an occupied memory module socket and remove the memory module.

20. The microfactory of claim 19, further comprising:
a scanner to scan the removed memory module;
the processing system to classify the removed memory module based on data from the scanner; and
the end-of-arm tool to place the removed memory module in a selected collection station based on the classifying.
